(19) United States
(12) Patent Application Publication
(10) Pub. No.: US 2025/0183190 A1
(43) Pub. Date: Jun. 5, 2025

(54) MODULE

(71) Applicant: Murata Manufacturing Co., Ltd., Kyoto-fu (JP)

(72) Inventor: Yoshihito OTSUBO, Nagaokakyo-shi (JP)

(21) Appl. No.: 19/043,223

(22) Filed: Jan. 31, 2025

Related U.S. Application Data
(63) Continuation of application No. PCT/JP2023/025938, filed on Jul. 13, 2023.

(30) Foreign Application Priority Data
Aug. 1, 2022 (JP) 2022-122644

(51) Int. Cl. H01L 23/538; H01L 23/31; H01L 25/11

(52) U.S. Cl. CPC H01L 23/5386; H01L 23/5385; H01L 25/112; H01L 23/3107

(57) ABSTRACT

A module includes: a substrate having a first surface; a first component mounted on the first surface; a first sealing resin layer disposed to cover a side surface of the first component and the first surface; and a redistribution layer covering a surface of the first sealing resin layer on a side far from the substrate. The redistribution layer includes: a first metal film disposed to correspond to a projection area of the first component; a first insulating film covering a surface of the first metal film on a side far from the substrate; and a first group of conductor vias passing through the first insulating film and protruding from the first metal film in a direction away from the substrate.

### CROSS REFERENCE TO RELATED APPLICATION

This is a continuation of International Application No. PCT/JP2023/025938 filed on Jul. 13, 2023 which claims priority from Japanese Patent Application No. 2022-122644 filed on Aug. 1, 2022. The contents of these applications are incorporated herein by reference in their entireties.

### BACKGROUND OF THE DISCLOSURE

### Field of the Disclosure

The present disclosure relates to a module.

### Description of the Related Art

U.S. Patent Application Publication No. US2017/0358560A1 discloses a semiconductor device in which components are mounted on both sides of a wiring substrate. This semiconductor device includes a redistribution layer on its surface on the side close to a motherboard.

### BRIEF SUMMARY OF THE DISCLOSURE

Heat is generated from each component mounted on a substrate of a module. The generated heat needs to be efficiently released in order to allow each component to keep operating normally.

Thus, it is a possible benefit of the present disclosure to provide a module improved in heat dissipation performance.

In order to achieve the above-mentioned possible benefit, a module according to the present disclosure includes: a substrate having a first surface; a first component mounted on the first surface; a first sealing resin layer disposed to cover a side surface of the first component and the first surface; and a redistribution layer covering a surface of the first sealing resin layer on a side far from the substrate. The redistribution layer includes: a first metal film disposed to correspond to a projection area of the first component; a first insulating film covering a surface of the first metal film on a side far from the substrate; and a first group of conductor vias passing through the first insulating film and protruding from the first metal film in a direction away from the substrate. The first group of conductor vias is exposed on a surface of the redistribution layer on a side far from the substrate, or a metal member connected to the first group of conductor vias is exposed on the surface of the redistribution layer on the side far from the substrate.

According to the present disclosure, the heat generated in the first component is transmitted to the first group of conductor vias through the first metal film, so that the heat can quickly reach the surface of the redistribution layer on the side far from the substrate. Therefore, heat is efficiently dissipated from this surface to the outside. In this way, a module improved in heat dissipation performance can be provided.

### BRIEF DESCRIPTION OF THE SEVERAL VIEWS OF THE DRAWINGS

FIG. 1 is a cross-sectional view of a module in a first embodiment according to the present disclosure.

FIG. 2 is a bottom view of the module in the first embodiment according to the present disclosure.

FIG. 3 is a diagram showing dashed lines for representing outlines of first metal films in FIG. 2.

FIG. 4 is a perspective bottom view of the module in the first embodiment according to the present disclosure.

FIG. 5 is a perspective bottom view of a first modification of the module in the first embodiment according to the present disclosure.

FIG. 6 is a perspective bottom view of a second modification of the module in the first embodiment according to the present disclosure.

FIG. 7 is a cross-sectional view of a module in a second embodiment according to the present disclosure.

FIG. 8 is a perspective bottom view of a module in a third embodiment according to the present disclosure.

FIG. 9 is a cross-sectional view taken along a line IX-IX in FIG. 8.

FIG. 10 is a perspective bottom view of a first modification of the module in the third embodiment according to the present disclosure.

FIG. 11 is a cross-sectional view taken along a line XI-XI in FIG. 10.

FIG. 12 is a perspective bottom view of a second modification of the module in the third embodiment according to the present disclosure.

FIG. 13 is a cross-sectional view taken along a line XIII-XIII in FIG. 12.

FIG. 14 is a perspective bottom view of a third modification of the module in the third embodiment according to the present disclosure.

FIG. 15 is a cross-sectional view taken along a line XV-XV in FIG. 14.

FIG. 16 is a perspective plan view of a module in a fourth embodiment according to the present disclosure.

FIG. 17 is a cross-sectional view taken along a line XVII-XVII in FIG. 16.

FIG. 18 is a cross-sectional view of a module in a fifth embodiment according to the present disclosure.

### DETAILED DESCRIPTION OF THE DISCLOSURE

The dimensional ratio shown in the accompanying drawings does not necessarily faithfully show the actual dimensional ratio, but the dimensional ratio may be exaggerated for the sake of convenience of description. In the following description, the concept “upper” or “lower” does not necessarily indicate an absolute upper or lower side, but may indicate a relatively upper or lower side in terms of position shown in each figure.

### First Embodiment

A module in the first embodiment according to the present disclosure will be hereinafter described with reference to FIGS. 1 to 3. FIG. 1 shows a cross-sectional view of a module 101 in the present embodiment. Module 101 includes: a substrate 1 having a first surface 1a; a first component 31 mounted on first surface 1a; a first sealing resin layer 61 disposed to cover a side surface of first component 31 and the first surface; and a redistribution layer 13 covering a surface of first sealing resin layer 61 on the side far from substrate 1. In the example shown herein, substrate 1 includes a plurality of insulating layers 2 that are stacked. Redistribution layer 13 includes a first layer 13a and a second layer 13b. In redistribution layer 13, first layer 13a is disposed on the side close to substrate 1, and second layer 13b is disposed on the side far from substrate 1. Second layer 13b forms the lowermost surface of module 101. In addition to first component 31, for example, a second component 32 is mounted on first surface 1a of substrate 1.

Redistribution layer 13 includes: a first metal film 41a disposed to correspond to a projection area of first component 31; a first insulating film 121 covering the surface of first metal film 41a on the side far from substrate 1; and a first group of conductor vias 161 passing through first insulating film 121 and protruding from first metal film 41a in the direction away from substrate 1.

In the example shown herein, redistribution layer 13 includes metal films 45a and 45b. Redistribution layer 13 includes a second insulating film 122. The first group of conductor vias 161 is connected to metal film 45a. A second group of conductor vias 162 is disposed to protrude from metal film 45a. The second group of conductor vias 162 passes through second insulating film 122. The second group of conductor vias 162 has a lower end exposed on a lower surface of redistribution layer 13.

Module 101 includes a columnar conductor 14. Columnar conductor 14 is disposed to pass through first sealing resin layer 61. Columnar conductor 14 has an upper end connected to a pad electrode disposed on first surface 1a of substrate 1. Columnar conductor 14 has a lower end connected to a conductor pattern included in first layer 13a of redistribution layer 13. Redistribution layer 13 includes several conductor patterns and conductor vias in first layer 13a and second layer 13b. The lower end of columnar conductor 14 is electrically routed out to the lower surface of redistribution layer 13 through these conductor patterns and conductor vias.

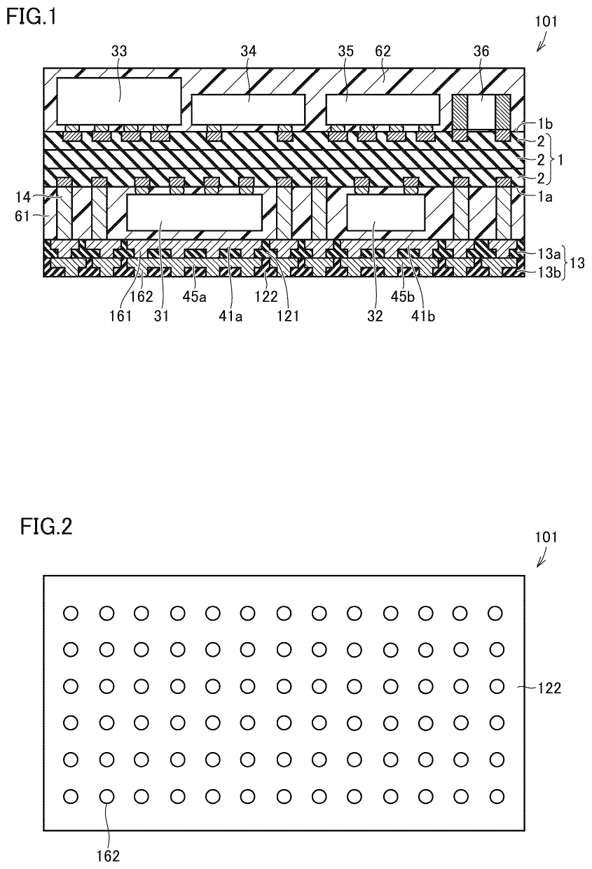

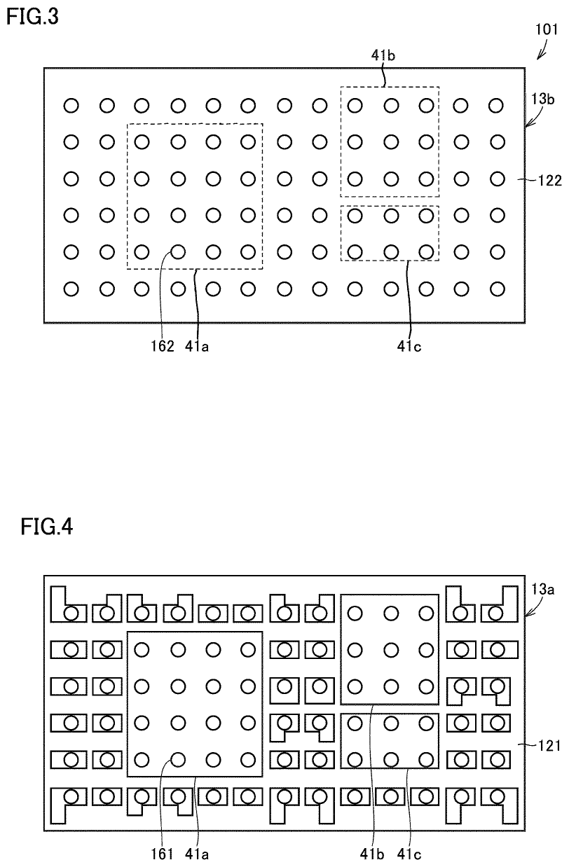

FIG. 2 shows a lower surface of module 101. In FIG. 2, the lower surface of redistribution layer 13 can be seen. In this case, terminals are arranged at equal intervals. FIG. 3 shows dashed lines for representing the outlines of first metal film 41a and the like hidden behind the insulating film in FIG. 2.

Further, FIG. 4 shows a bottom view of module 101 from which second layer 13b has been removed. For convenience of description, however, FIG. 4 shows module 101 based on the assumption that first insulating film 121 is transparent. In other words, FIG. 4 also shows portions of first metal film 41a and the like that are covered with first insulating film 121. The diagram shown according to such a manner of illustration applied to FIG. 4 is herein referred to as a “perspective bottom view”. This manner of illustration is similarly applied to FIGS. 5, 6, 8, 10, 12, and the like, which will be described later.

The “first metal film” included in redistribution layer 13 is not limited only to first metal film 41a. In the example shown herein, redistribution layer 13 also includes first metal films 41b and 41c in addition to first metal film 41a.

In the example shown herein, first metal films 41a, 41b, and 41c belong to first layer 13a. Metal films 45a and 45b belong to second layer 13b.

The first group of conductor vias 161 is exposed on the surface of redistribution layer 13 on the side far from substrate 1, or a metal member connected to the first group of conductor vias 161 is exposed on the surface of redistribution layer 13 on the side far from substrate 1. More specifically, in the present embodiment, the metal member connected to the first group of conductor vias 161 is exposed on the surface of redistribution layer 13 on the side far from substrate 1. The “metal member” as used herein refers to metal film 45a and the second group of conductor vias 162. The lower surface of the second group of conductor vias 162 is exposed as a terminal in FIG. 2.

Substrate 1 has a second surface 1b as a surface on the side opposite to first surface 1a. In the example shown herein, components 33, 34, 35, and 36 are mounted on second surface 1b. Second surface 1b and components 33, 34, 35, and 36 are sealed with a second sealing resin 62.

In the present embodiment, the heat generated in first component 31 is transmitted to first metal film 41a disposed to correspond to the projection area of first component 31, and further transmitted to the first group of conductor vias 161 that pass through first insulating film 121. The first group of conductor vias 161 is exposed on the surface of redistribution layer 13 on the side far from substrate 1, or the metal member connected to the first group of conductor vias 161 is exposed on the surface of redistribution layer 13 on the side far from substrate 1. Accordingly, the transmitted heat can quickly reach the surface of redistribution layer 13 on the side far from substrate 1. Also, the heat can be efficiently dissipated from this surface to the outside. Therefore, according to the present embodiment, a module improved in heat dissipation performance can be implemented.

As described in the present embodiment, it is preferable that redistribution layer 13 includes second insulating film 122 disposed to overlap with first insulating film 121 on the side of first insulating film 121 far from substrate 1, redistribution layer 13 includes the second group of conductor vias 162 electrically connected to at least one of the conductor vias belonging to the first group of conductor vias 161, and the second group of conductor vias 162 passes through second insulating film 122. Adopting this configuration makes it possible to transmit heat to the surface of redistribution layer 13 through the second group of conductor vias 162, so that the heat can be efficiently dissipated.

In module 101, the second group of conductor vias 162 is arranged in the same manner as that for the first group of conductor vias 161.

As described in the present embodiment, it is preferable that first sealing resin layer 61 is interposed between first component 31 and redistribution layer 13. This is because first component 31 can be protected by adopting this configuration. In particular, first sealing resin layer 61 can prevent moisture entering through redistribution layer 13 from reaching first component 31.

As described in the present embodiment, it is preferable that the conductors arranged in a dotted manner are exposed at equal intervals on the surface of redistribution layer 13 on the side far from substrate 1. The conductors arranged in a dotted manner serve as terminals for connecting to a motherboard or the like. Adopting this configuration facilitates a connection to a motherboard or the like.

### First Modification

The first modification of the present embodiment will be hereinafter described. A module in the first modification has a configuration shown in FIG. 5 in place of the configuration shown in FIG. 4. FIG. 5 shows the arrangement of the first group of conductor vias 161. The arrangement of the second group of conductor vias 162 is the same as that shown in FIG. 3. In other words, in the module in the first modification, the first group of conductor vias 161 (see FIG. 5) is arranged at a density higher than the density at which the second group of conductor vias 162 is arranged (see FIG. 3), and the conductor vias belonging to the first group of conductor vias 161 are larger in number than the conductor vias belonging to the second group of conductor vias 162. In the example shown herein, the number of conductor vias belonging to the first group of conductor vias 161 is 25, and the number of conductor vias belonging to the second group of conductor vias 162 is 16. Adopting this configuration increases the number of paths through which heat is transmitted from first metal film 41a to metal film 45a inside redistribution layer 13, and therefore, the heat transmitted from first component 31 to first metal film 41a can be efficiently transmitted to metal film 45a, so that heat dissipation is facilitated. Since the lower surface of the second group of conductor vias 162 that is exposed on the lowermost surface of redistribution layer 13 serves as a connection terminal, the second group of conductor vias 162 is preferably arranged according to a predetermined manner of arrangement. In the first modification, however, the first group of conductor vias 161 is not exposed on the lowermost surface of redistribution layer 13, and thus, can be arranged at a high density without having to follow the rule for arrangement of the connection terminals.

### Second Modification

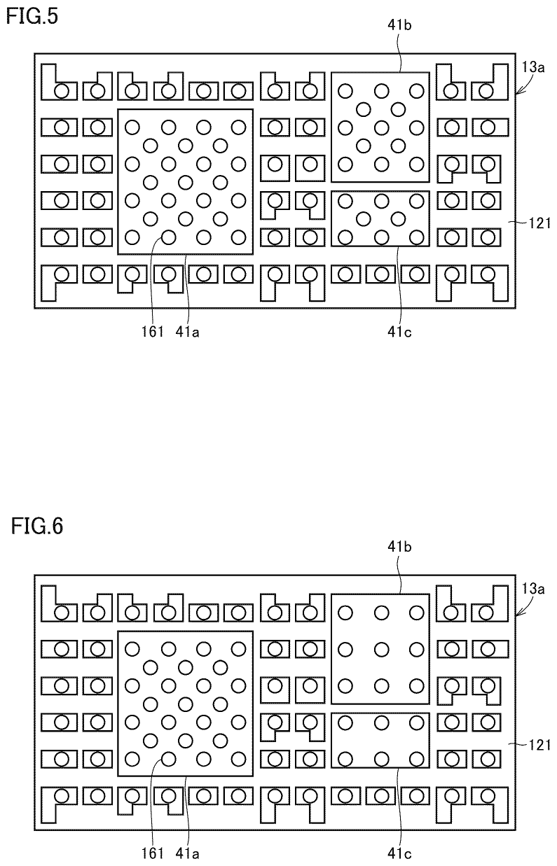

The second modification of the present embodiment will be hereinafter described. A module in the second modification has a configuration shown in FIG. 6 in place of the configuration shown in FIG. 4. The first group of conductor vias 161 protruding from first metal film 41a is higher in density than the group of conductor vias protruding from first metal film 41b. In the case where it is first component 31 for which heat dissipation should be most facilitated, it is conceivable that the first group of conductor vias 161 protruding from first metal film 41a corresponding to first component 31 may be formed to be relatively higher in density than the group of conductor vias protruding from each of the metal films corresponding to other components in this way. This makes it possible to actually facilitate the heat dissipation from the component for which heat dissipation should be most facilitated. In this way, the conductor vias arranged in the same layer may be arranged so as to be changed in density according to the corresponding component.

### Second Embodiment

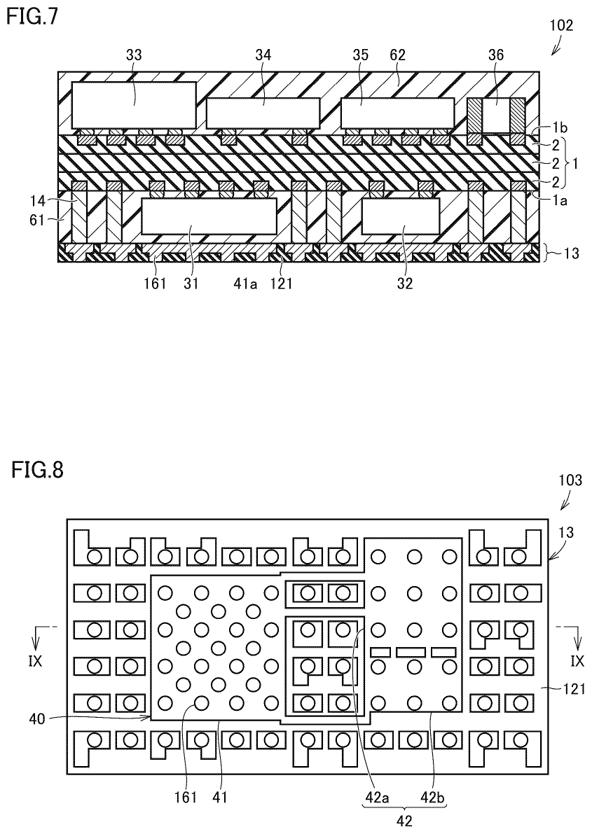

A module in the second embodiment according to the present disclosure will be hereinafter described with reference to FIG. 7. FIG. 7 shows a cross-sectional view of a module 102 in the present embodiment.

In module 101 described in the first embodiment, redistribution layer 13 has a two-layer structure including roughly divided two layers. In module 102 in the present embodiment, however, redistribution layer 13 has a single-layer structure in place of a two-layer structure. Redistribution layer 13 includes first metal film 41a and first insulating film 121. Redistribution layer 13 includes the first group of conductor vias 161 passing through first insulating film 121 and protruding from first metal film 41a in the direction away from substrate 1. In module 102, the first group of conductor vias 161 is exposed on the surface of redistribution layer 13 on the side far from substrate 1.

In the present embodiment, the heat generated in first component 31 is transmitted to the first group of conductor vias 161 through first metal film 41a. Since the lower end of the first group of conductor vias 161 is exposed from redistribution layer 13, heat is quickly dissipated to the outside. Therefore, according to the present embodiment, a module improved in heat dissipation performance can be implemented.

### Third Modification

A module in the third embodiment according to the present disclosure will be hereinafter described with reference to FIGS. 8 and 9. FIG. 8 shows a perspective bottom view of a module 103 in the present embodiment. FIG. 9 shows a cross-sectional view taken along a line IX-IX in FIG. 8. As shown in FIGS. 8 and 9, when referring to the perspective bottom view and the cross-sectional view, it means a cross-sectional view of the entire module instead of the module from which some of the layers have been removed. The same also applies to other figures described below.

Module 103 includes a first metal film 41 and a second metal film 42 in redistribution layer 13.

Module 103 includes second component 32 as another component mounted on first surface 1a. Redistribution layer 13 includes a second metal film 42a disposed to correspond to the projection area of this another component, i.e., second component 32, in which second metal film 42a is grounded. First metal film 41a and second metal film 42a are contiguous to each other. Further, redistribution layer 13 includes a second metal film 42b that is grounded. Second metal films 42a and 42b are ground conductor patterns. Second metal film 42 includes second metal films 42a and 42b. As shown in FIG. 8, first metal film 41a and second metal film 42b may also be contiguous to each other. Second metal films 42a and 42b may also be contiguous to each other.

In this case, by way of example, first metal film 41a and second metal film 42a are connected by a bridge-shaped portion. The bridge-shaped portion is disposed to avoid the conductor pattern leading to the terminal disposed between the projection area of first component 31 and the projection area of second component 32.

In the present embodiment, each component mounted on first surface 1a of substrate 1 is improved in heat dissipation performance. In the present embodiment, the ground connection can be strengthened for a ground terminal around each component.

### First Modification

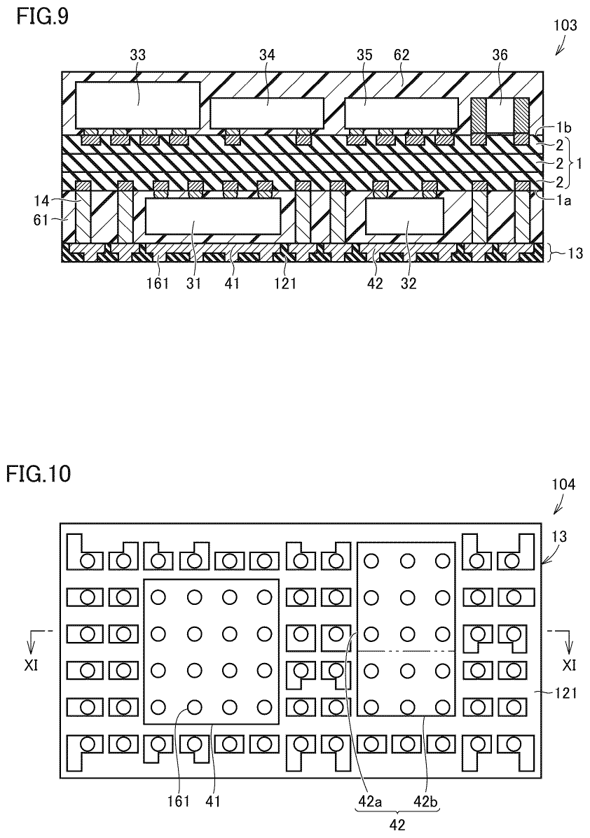

In the example of module 103 shown in FIG. 8, second metal films 42a and 42b are connected by a bridge-shaped portion, which is however merely by way of example. The first modification of the present embodiment will be hereinafter described with reference to FIGS. 10 and 11. In a module 104 shown in FIG. 10, second metal films 42a and 42b are directly contiguous to each other over the entire width. FIG. 10 shows a two-dot chain line indicating an imaginary boundary line between second metal films 42a and 42b. FIG. 11 shows a cross-sectional view taken along a line XI-XI in FIG. 10. In the first modification, since second metal films 42a and 42b are contiguous to be integrated with each other, a large conductor pattern of second metal film 42 is disposed as an integrated ground conductor pattern.

### Second Modification

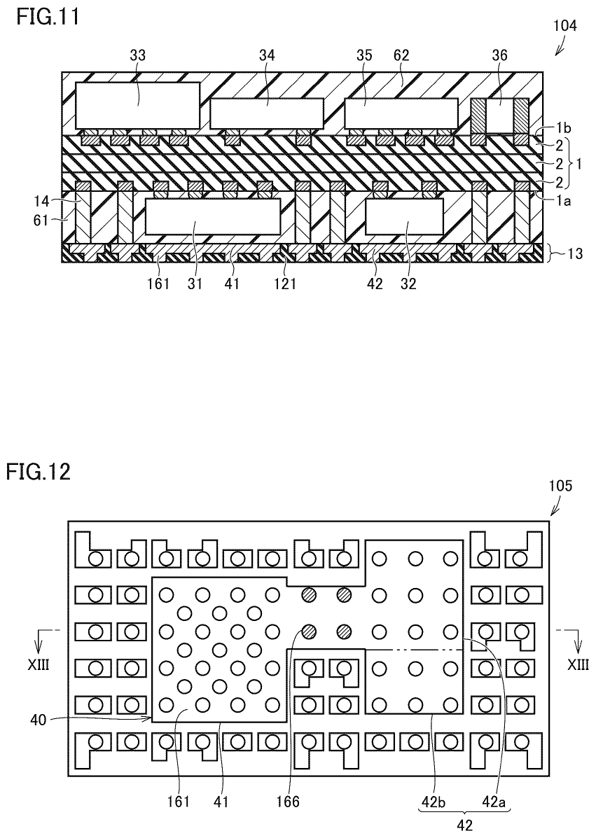

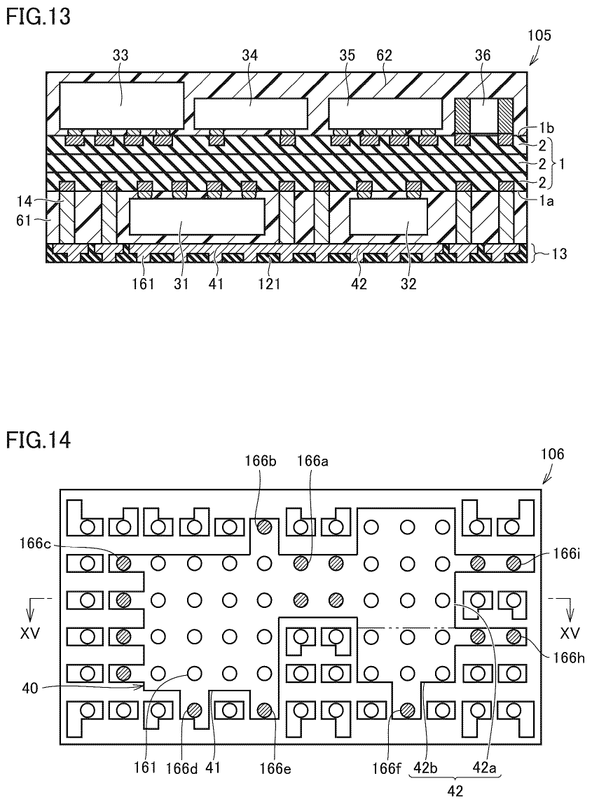

The second modification of the present embodiment will be hereinafter described with reference to FIGS. 12 and 13. In a module 105 shown in FIG. 12, second metal films 42a and 42b are directly contiguous to each other over the entire width. Further, first metal film 41 is also contiguously provided. The integrated metal film 40 including first metal film 41, second metal film 42a, and second metal film 42b incorporates a ground conductor via 166 contiguous to a terminal disposed between the projection area of first component 31 and the projection area of second component 32. Since metal film 40 is connected to ground conductor via 166, it can be recognized as a ground conductor pattern. In FIG. 12, each of the conductor vias for signal transmission and ground connection is shown as a circle, whereas each ground conductor via 166 is shown as a hatched circle. FIG. 12 shows four ground conductor vias 166. FIG. 13 shows a cross-sectional view taken along a line XIII-XIII in FIG. 12.

Module 105 may be represented as follows. Module 105 includes ground conductor via 166 as columnar conductor 14 disposed to pass through first sealing resin layer 61. Redistribution layer 13 includes a conductor structure in a projection area of each columnar conductor 14. This conductor structure is connected to columnar conductor 14 and provides an electrical connection from the surface of redistribution layer 13 on the side close to substrate 1 to the surface of redistribution layer 13 on the side far from substrate 1. First metal film 41 is contiguous to the conductor structure.

### Third Modification

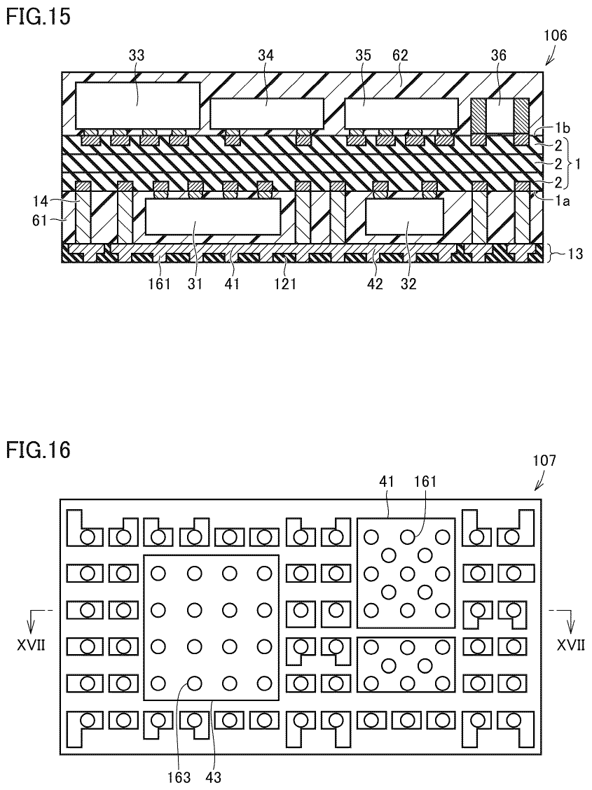

The third modification of the present embodiment will be hereinafter described with reference to FIGS. 14 and 15. A module 106 shown in FIG. 14 includes a metal film 40 that is further increased in area as compared with the integrated metal film 40 in module 105. The integrated metal film 40 including first metal film 41, second metal film 42a, and second metal film 42b not only incorporates a ground conductor via 166a leading to a terminal disposed between the projection area of first component 31 and the projection area of second component 32, but also incorporates ground conductor vias 166b, 166c, 166d, 166e, 166f, 166h, and 166i leading to terminals disposed around the projection area of first component 31 and the projection area of second component 32 so as to extend as an integral one-piece metal film 40. It can also be said that metal film 40 is a ground conductor pattern. In FIG. 14, each of the ground conductor vias is shown as a hatched circle. First metal film 41 includes a portion bulging toward each of ground conductor vias 166b, 166c, 166d, and 166e. Second metal film 42b includes a portion bulging toward each of ground conductor vias 166f and 166h. Second metal film 42a includes a portion bulging toward ground conductor via 166i. FIG. 15 shows a cross-sectional view taken along a line XV-XV in FIG. 14.

Module 106 may be represented as follows. Module 106 includes a group of columnar conductors disposed to pass through first sealing resin layer 61 and to surround the projection area of first component 31. First metal film 41 includes a bulging portion extending outward from the projection area of first component 31, and the group of columnar conductors is connected to the bulging portion. The group of columnar conductors mentioned herein is, for example, a group including ground conductor vias 166c, 166d, and 166e.

### Fourth Embodiment

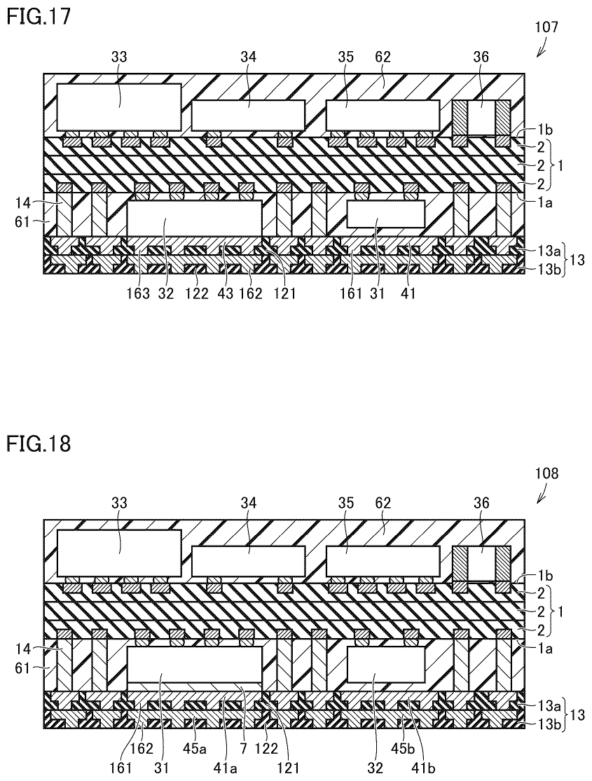

A module in the fourth embodiment according to the present disclosure will be hereinafter described with reference to FIGS. 16 and 17. FIG. 16 shows a perspective bottom view of a module 107 in the present embodiment. FIG. 17 shows a cross-sectional view taken along a line XVII-XVII in FIG. 16.

Module 107 includes first component 31 and second component 32. It should be noted that the arrangement of first component 31 and second component 32 in the figures in the present embodiment is reversed from the arrangement in each of the first to third embodiments. First metal film 41 is disposed to correspond to the projection area of first component 31.

Module 107 includes second component 32 mounted on first surface 1a. In module 107, redistribution layer 13 includes a third metal film 43 in a region not overlapping with first metal film 41. Second component 32 and third metal film 43 are in contact with each other. Module 107 includes a third group of conductor vias 163 passing through first insulating film 121 and protruding from third metal film 43 in the direction away from substrate 1. As shown in FIG. 16, the first group of conductor vias 161 is arranged at a density higher than the density at which the third group of conductor vias 163 is arranged.

In the present embodiment, heat dissipation from first component 31 can be facilitated while facilitating heat dissipation from second component 32 mounted on first surface 1a. Therefore, according to the present embodiment, a module improved in heat dissipation performance can be implemented.

### Fifth Embodiment

A module in the fifth embodiment according to the present disclosure will be hereinafter described with reference to FIG. 18. FIG. 18 shows a cross-sectional view of a module 108 in the present embodiment.

Module 108 has the same basic configuration as that of module 101 described in the first embodiment, but is different therefrom in the following points. In module 108, a thermal interface material (TIM) layer 7 is interposed between first component 31 and first metal film 41a, first component 31 is in contact with TIM layer 7, and TIM layer 7 is in contact with first metal film 41a.

TIM layer 7 is made of a thermally conductive material. In other words, TIM layer 7 is made of a material suitable for heat conduction. The material of TIM layer 7 is not electrically conductive. The material of TIM layer 7 may be, for example, an epoxy resin mixed with a metal. The metal mixed in this case may be, for example, gold, silver, or the like. TIM layer 7 may be formed of thermal grease, white grease, or the like. TIM layer 7 may be formed by combining two or more of thermal grease, white grease, and the like.

The material of TIM layer 7 may be any one of an epoxy resin, silicone, an inorganic material, and a matrix polymer. The material of TIM layer 7 may be a polymer mixed with a thermally conductive filler. The matrix polymer may include one selected from the group consisting of ethylene propylene, an ethylene propylene diene monomer, and hydrogenated polyisoprene, or may be a combination of two or more selected from the group. TIM layer 7 may include one selected from the group consisting of aluminum oxide, boron nitride, and aluminum nitride, or may be a combination of two or more selected from the group.

TIM layer 7 may include one selected from the group consisting of carbon nanotubes, graphite, graphene, a polyimide resin, polybenzoxazole, an epoxy-based polymer, a silica-based polymer, and an acrylic-based polymer, or may be a combination of two or more selected from the group. TIM layer 7 may include a filler. The thermal conductivity of the material of TIM layer 7 may be 5 W/(m·K) or more and 100 W/(m·K) or less. Further, the thermal conductivity of the material of TIM layer 7 is preferably 10 W/(m·K) or more and 90 W/(m·K) or less. Further, the thermal conductivity of the material of TIM layer 7 is preferably 20 W/(m·K) or more and 80 W/(m·K) or less. The material of TIM layer 7 may have a structure in which polymers are bonded to a liquid metal by organometallic bonding, coordination bonding, or covalent bonding.

In the present embodiment, the heat generated in first component 31 is transmitted to first metal film 41a through TIM layer 7, and further transmitted to the first group of conductor vias 161 that pass through first insulating film 121. Therefore, according to the present embodiment, the same effect as that achieved in the first embodiment can be achieved, and a module improved in heat dissipation performance can be implemented.

Among the above-described embodiments, a plurality of embodiments may be employed in an appropriate combination.

Note that the above-described embodiments disclosed herein are illustrative and non-restrictive in every respect. The scope of the present disclosure is defined by the terms of the claims, and is intended to include any modifications within the meaning and scope equivalent to the terms of the claims.

### Additional Aspect 1

A module including: a substrate having a first surface; a first component mounted on the first surface; a first sealing resin layer disposed to cover a side surface of the first component and the first surface; and a redistribution layer covering a surface of the first sealing resin layer on a side far from the substrate, wherein the redistribution layer includes a first metal film disposed to correspond to a projection area of the first component, a first insulating film covering a surface of the first metal film on a side far from the substrate, and a first group of conductor vias passing through the first insulating film and protruding from the first metal film in a direction away from the substrate, and the first group of conductor vias is exposed on a surface of the redistribution layer on a side far from the substrate, or a metal member connected to the first group of conductor vias is exposed on the surface of the redistribution layer on the side far from the substrate.

### Additional Aspect 2

The module according to Additional Aspect 1, wherein the redistribution layer includes a second insulating film disposed on a side of the first insulating film far from the substrate to overlap with the first insulating film, the redistribution layer includes a second group of conductor vias electrically connected to at least one of conductor vias belonging to the first group of conductor vias, and the second group of conductor vias passes through the second insulating film.

### Additional Aspect 3

The module according to Additional Aspect 2, wherein the first group of conductor vias is arranged at a density higher than a density at which the second group of conductor vias is arranged, and the conductor vias belonging to the first group of conductor vias are larger in number than conductor vias belonging to the second group of conductor vias.

### Additional Aspect 4

The module according to any one of Additional Aspects 1 to 3, wherein the first sealing resin layer is interposed between the first component and the redistribution layer.

### Additional Aspect 5

The module according to any one of Additional Aspects 1 to 4, including another component mounted on the first surface, wherein the redistribution layer includes a second metal film disposed to correspond to a projection area of the other component, the second metal film being grounded, and the first metal film and the second metal film are contiguous to each other.

### Additional Aspect 6

The module according to any one of Additional Aspects 1 to 5, including a columnar conductor disposed to pass through the first sealing resin layer, wherein the redistribution layer includes a conductor structure in a projection area of the columnar conductor, the conductor structure is connected to the columnar conductor and provides an electrical connection from a surface of the redistribution layer on a side close to the substrate to a surface of the redistribution layer on a side far from the substrate, and the first metal film and the conductor structure are contiguous to each other.

### Additional Aspect 7

The module according to any one of Additional Aspects 1 to 6, including a group of columnar conductors disposed to pass through the first sealing resin layer and to surround the projection area of the first component, wherein the first metal film includes a bulging portion extending outward from the projection area of the first component, and the group of columnar conductors is connected to the bulging portion.

### Additional Aspect 8

The module according to any one of Additional Aspects 1 to 7, wherein conductors arranged in a dotted manner are exposed at equal intervals on the surface of the redistribution layer on the side far from the substrate.

### Additional Aspect 9

The module according to any one of Additional Aspects 1 to 8, including a second component mounted on the first surface, wherein the redistribution layer includes a third metal film in a region not overlapping with the first metal film, the second component and the third metal film are in contact with each other, the module includes a third group of conductor vias passing through the first insulating film and protruding from the third metal film in a direction away from the substrate, and the first group of conductor vias is arranged at a density higher than a density at which the third group of conductor vias is arranged.
1 substrate, 1a first surface, 1b second surface, 2 insulating layer, 7 TIM layer, 13 redistribution layer, 13a first layer, 13b second layer, 14 columnar conductor, 31 first component, 32 second component, 33, 34, 35, 36 component, 40 metal film, 41, 41a, 41b, 41c first metal film, 42, 42a, 42b, 42c second metal film, 43 third metal film, 45a, 45b metal film, 61 first sealing resin layer, 62 second sealing resin layer, 101, 102, 103, 104, 105, 106, 107, 108 module, 121 first insulating film, 122 second insulating film, 161 first group of conductor vias, 162 second group of conductor vias, 163 third group of conductor vias, 166, 166a, 166b, 166c, 166d, 166e, 166f, 166h, 166i ground conductor via.

1. A module comprising:
a substrate having a first surface;
a first component mounted on the first surface;
a first sealing resin layer disposed to cover the first surface and a side surface of the first component; and
a redistribution layer covering a surface of the first sealing resin layer on a side farther from the substrate, wherein
the redistribution layer includes
a first metal film disposed to correspond to a projection area of the first component,
a first insulating film covering a surface of the first metal film on a side farther from the substrate, and
a first group of conductor vias passing through the first insulating film and protruding from the first metal film in a direction away from the substrate, and
the first group of conductor vias is exposed on a surface of the redistribution layer on a side farther from the substrate, or a metal member connected to the first group of conductor vias is exposed on the surface of the redistribution layer on the side farther from the substrate.

2. The module according to claim 1, wherein the redistribution layer includes a second insulating film disposed on a side of the first insulating film farther from the substrate to overlap with the first insulating film, the redistribution layer includes a second group of conductor vias electrically connected to at least one of conductor vias belonging to the first group of conductor vias, and the second group of conductor vias passes through the second insulating film.

3. The module according to claim 2, wherein the first group of conductor vias is arranged at a density higher than a density at which the second group of conductor vias is arranged, and the conductor vias belonging to the first group of conductor vias are larger in number than conductor vias belonging to the second group of conductor vias.

4. The module according to claim 1, wherein the first sealing resin layer is interposed between the first component and the redistribution layer.

5. The module according to claim 1, comprising another component mounted on the first surface, wherein
the redistribution layer includes a second metal film disposed to correspond to a projection area of the other component, the second metal film being grounded, and
the first metal film and the second metal film are contiguous to each other.

6. The module according to claim 1, comprising a columnar conductor disposed to pass through the first sealing resin layer, wherein
the redistribution layer includes a conductor structure in a projection area of the columnar conductor, the conductor structure is connected to the columnar conductor and provides an electrical connection from a surface of the redistribution layer on a side closer to the substrate to a surface of the redistribution layer on a side farther from the substrate, and the first metal film and the conductor structure are contiguous to each other.

7. The module according to claim 1, comprising a group of columnar conductors disposed to pass through the first sealing resin layer and to surround the projection area of the first component, wherein
the first metal film includes a bulging portion extending outward from the projection area of the first component, and the group of columnar conductors is connected to the bulging portion.

8. The module according to claim 1, wherein conductors arranged in a dotted manner are exposed at equal intervals on the surface of the redistribution layer on the side farther from the substrate.

9. The module according to claim 1, comprising a second component mounted on the first surface, wherein
the redistribution layer includes a third metal film in a region not overlapping with the first metal film,
the second component and the third metal film are in contact with each other,
the module comprises a third group of conductor vias passing through the first insulating film and protruding from the third metal film in a direction away from the substrate, and
the first group of conductor vias is arranged at a density higher than a density at which the third group of conductor vias is arranged.

10. The module according to claim 1, wherein a TIM layer is interposed between the first component and the first metal film, the first component and the TIM layer are in contact with each other, and the TIM layer and the first metal film are in contact with each other.

11. The module according to claim 2, wherein the first sealing resin layer is interposed between the first component and the redistribution layer.

12. The module according to claim 3, wherein the first sealing resin layer is interposed between the first component and the redistribution layer.

13. The module according to claim 2, comprising another component mounted on the first surface, wherein
the redistribution layer includes a second metal film disposed to correspond to a projection area of the other component, the second metal film being grounded, and
the first metal film and the second metal film are contiguous to each other.

14. The module according to claim 3, comprising another component mounted on the first surface, wherein
the redistribution layer includes a second metal film disposed to correspond to a projection area of the other component, the second metal film being grounded, and
the first metal film and the second metal film are contiguous to each other.

15. The module according to claim 4, comprising another component mounted on the first surface, wherein
the redistribution layer includes a second metal film disposed to correspond to a projection area of the other component, the second metal film being grounded, and
the first metal film and the second metal film are contiguous to each other.

16. The module according to claim 2, comprising a columnar conductor disposed to pass through the first sealing resin layer, wherein
the redistribution layer includes a conductor structure in a projection area of the columnar conductor, the conductor structure is connected to the columnar conductor and provides an electrical connection from a surface of the redistribution layer on a side closer to the substrate to a surface of the redistribution layer on a side farther from the substrate, and the first metal film and the conductor structure are contiguous to each other.

17. The module according to claim 3, comprising a columnar conductor disposed to pass through the first sealing resin layer, wherein
the redistribution layer includes a conductor structure in a projection area of the columnar conductor, the conductor structure is connected to the columnar conductor and provides an electrical connection from a surface of the redistribution layer on a side closer to the substrate to a surface of the redistribution layer on a side farther from the substrate, and the first metal film and the conductor structure are contiguous to each other.

18. The module according to claim 4, comprising a columnar conductor disposed to pass through the first sealing resin layer, wherein
the redistribution layer includes a conductor structure in a projection area of the columnar conductor, the conductor structure is connected to the columnar conductor and provides an electrical connection from a surface of the redistribution layer on a side closer to the substrate to a surface of the redistribution layer on a side farther from the substrate, and the first metal film and the conductor structure are contiguous to each other.

19. The module according to claim 5, comprising a columnar conductor disposed to pass through the first sealing resin layer, wherein
the redistribution layer includes a conductor structure in a projection area of the columnar conductor, the conductor structure is connected to the columnar conductor and provides an electrical connection from a surface of the redistribution layer on a side closer to the substrate to a surface of the redistribution layer on a side farther from the substrate, and the first metal film and the conductor structure are contiguous to each other.

20. The module according to claim 2, comprising a group of columnar conductors disposed to pass through the first sealing resin layer and to surround the projection area of the first component, wherein
the first metal film includes a bulging portion extending outward from the projection area of the first component, and the group of columnar conductors is connected to the bulging portion.
